(19) United States
(12) Patent Application Publication
(10) Pub. No.: US 2014/0345663 A1
(43) Pub. Date: Nov. 27, 2014

(54) THERMOELECTRIC DEVICE AND THERMOELECTRIC MODULE USING THE SAME

(71) Applicants: Jun Hayakawa, Tokyo (JP); Shin Yabuuchi, Tokyo (JP); Yosuke Kurosaki, Tokyo (JP); Akinori Nishide, Tokyo (JP); Masakuni Okamoto, Tokyo (JP)

(72) Inventors: Jun Hayakawa, Tokyo (JP); Shin Yabuuchi, Tokyo (JP); Yosuke Kurosaki, Tokyo (JP); Akinori Nishide, Tokyo (JP); Masakuni Okamoto, Tokyo (JP)

(21) Appl. No.: 14/366,689

(22) PCT Filed: Dec. 21, 2011
(86) PCT No.: PCT/JP2011/007146

§ 371 Date: Jun. 19, 2014

(51) Int. Cl. H01L 35/20; H01L 35/32

(52) U.S. Cl. CPC H01L 35/20; H01L 35/32
USPC 136/205

(57) ABSTRACT

Provided are a thermoelectric device and a thermoelectric module having larger conversion efficiency than conventional ones. A thermoelectric device of the present invention includes a Heusler alloy material, and a pair of electrodes that takes out electromotive force according to a temperature gradient caused in the Heusler alloy material. Further, the dimensions of the Heusler alloy material are defined such that the conversion efficiency of the module is maximized according to an environment having a temperature difference, under which the Heusler alloy material is used.

### TECHNICAL FIELD

The present invention relates to a thermoelectric device and a thermoelectric module having high conversion efficiency.

### BACKGROUND ART

Conversion of thermal energy to electric energy using Seebeck effect of substance is called thermoelectric conversion, and a device that realizes the thermoelectric conversion is a thermoelectric device. A material used for the thermoelectric device is called thermoelectric conversion material, and as an index to evaluate the efficiency of the thermoelectric conversion, there is a figure of merit Z=S²σ/κ (here, S is the Seebeck coefficient, σ is electrical conductivity, and κ is thermal conductivity).

As the thermoelectric conversion material, Heusler alloys configured from:

(1) a Bi—Te based, Pb—Te based, Si—Ge, or Mg—Si based compound semiconductor,

(2) an NaₓCoO₂ (0.3≦x≦0.8), (ZnO)mIn₂O₃ (1≦m≦19) based oxide material,

(3) a Zn—Sb based, Co—Sb based, Fe—Sb based skutterudite compound, and

(4) an intermetallic compound, such as Fe₂VA1 or ZrNiSn are known.

However, in such a conventional material, thermoelectromotive force is 300 μV/K or less, and a dimensionless figure of merit ZT (T is a temperature) is about 1. Especially, in recent years, a large number of oxide materials having thermally and chemically high stability have been reported. However, the thermoelectric conversion performance of these materials is lower than a typically used alloy material, and ZT of a bulk material is about 0.5. In the exhaust-heat recovery at an actual practical level, a material having ZT of 1 or more, more favorably, 2 or more is required.

Meanwhile, to realize an application to a thermoelectric conversion system, there is a thermoelectric module that configures an output source of the system. Prototypes of the thermoelectric module have been made using the above-described materials in the past, and it is imperative to enhance the thermoelectric conversion efficiency as a module and to improve a power output. Especially, how effectively providing a large temperature difference to the module is an important design guideline.

### SUMMARY OF INVENTION

### Technical Problem

An objective of the present invention is to provide a thermoelectric device and a thermoelectric module having higher conversion efficiency than conventional ones.

### Solution to Problem

A thermoelectric device and a thermoelectric module of the present invention select and use a Heusler alloy material having a large figure of merit, and define dimensions to maximize thermal energy provided to the module. Especially, as the Heusler alloy, elements X and Y that can realize ZT>1 are selected in a type of the Full-Heusler alloy configured from Fe₂XY. The thermoelectric module using the Full-Heusler alloy selected here is characterized in that the dimensions of the thermoelectric conversion material are set such that an effective temperature difference in the thermoelectric conversion material is maximized according to thermal energy that passes through the module in an environment under which the module is used.

### Advantageous Effects of Invention

According to the present invention, a figure of merit more than twice conventional ones can be realized.

### BRIEF DESCRIPTION OF DRAWINGS

FIG. 1 is a schematic diagram illustrating a configuration example of a thermoelectric device of the present invention.

FIG. 2 is schematic diagrams illustrating configuration examples of a thermoelectric module of the present invention.

FIGS. 3(a) to 3(h) are schematic diagrams illustrating configuration examples of a thermoelectric module of the present invention.

FIG. 4 is a schematic diagram illustrating a configuration example of a thermoelectric module of the present invention.

FIG. 5 is a diagram illustrating elements that configure a thermoelectric conversion material of the present invention.

FIG. 6 is a diagram illustrating an electron state of a thermoelectric conversion material of the present invention.

### DESCRIPTION OF EMBODIMENTS

Hereinafter, embodiments of the present invention will be described with reference to the drawings.

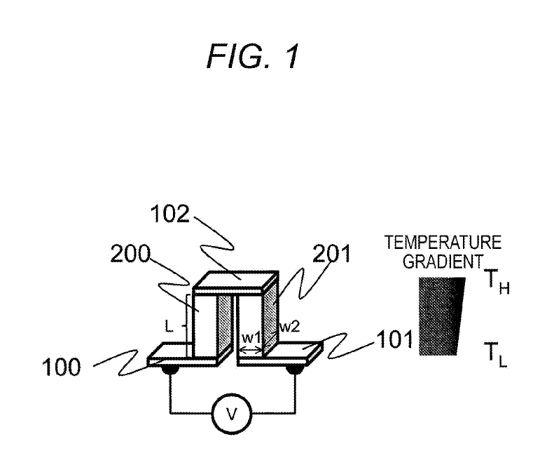

FIG. 1 is a schematic diagram illustrating a configuration example of a thermoelectric device according to the present invention. The thermoelectric device is configured from a pair of a p-type Full-Heusler alloy 200 and an n-type Full-Heusler alloy 201, an electrode 102 that connects the alloys 200 and 201, an electrode 100 connected to the p-type Full-Heusler alloy, and an electrode 101 connected to the n- type Full -Heusler alloy. Here, the thermoelectric device has a configuration in which a temperature T_{H} is provided to an upper portion (at the electrode 102 side) and a temperature T_{L}, is provided to a lower portion (at the electrodes 100 and 101 side) of the present thermoelectric device, and an electricity generated in Full-Heusler alloy portions is taken out from the electrodes 100 and 101 as power (a voltage or an electricity) when a gradient of a temperature difference ΔT (=T_{H}T_{L}) is applied to the both Full-Heusler alloys from the electrode 102 side to the electrodes 100 and 101 side.

Here, for the material of the Full-Heusler alloys 200 and 201 illustrated in Table 1, elements X and Y are selected such that the elements X and Y are described as Fe₂XY and the figure of merit ZT becomes large.

TABLE 1

| | Element X | Element Y |
|---|---|---|
| Fe | Ti | Si, Ge, Sn |
| | Zr | |
| | Hf | |
| | V | Al, Ga, In |
| | Nb | |
| | Ta | |
| | Cr | Zn, Cd, Hg, Mg, Ca, Sr, Ba |
| | Mo | |
| | W | |
| | Sc | P, As, Sb, Bi |
| | Y | |

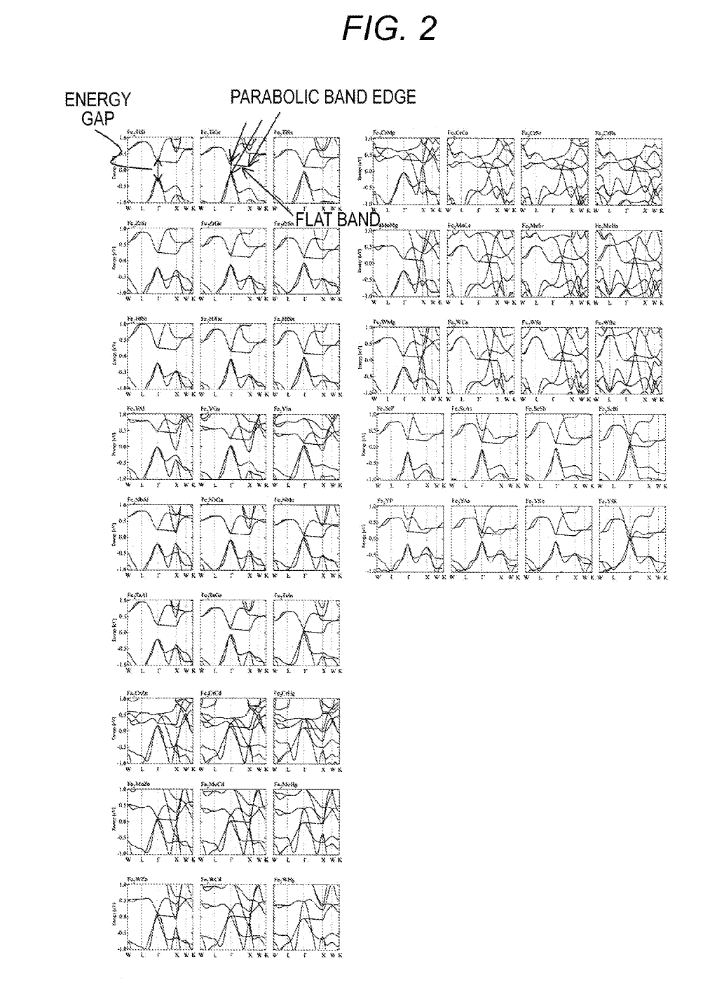

Specifically, it is desirable to select the elements illustrated in Table 1. Each element composition may be slightly larger or smaller than Fe₂XY. Specifically, Fe falls within a range of 2±0.3, X falls within a range of 1±0.2, and Y falls within a range of 1±0.2, and a sum of all composition (atomic weight) ratios becomes 4. Accordingly, the Seebeck coefficient can be maximized, and a high ZT can be obtained. Further, as for the elements X and Y, two types or more elements can be selected from the elements described in Table 1, respectively. For example, TiV can be selected as the element X, AlSi can be selected as the element Y, and a Heusler alloy configured from 5 elements, such as Fe₂(TiV)(AlSi), can be selected. The Heusler alloy materials indicated in Table 1 have electron states illustrated in FIG. 2, respectively. All of these selected Heusler alloys have small energy gaps (illustrated in FIG. 2) in the vicinity of the Fermi level (0.0 eV in the vertical axis in the drawing). Further, a material having a large figure of merit has a characteristic to form parabolic band edges in positions of the point P and the point X indicated in the horizontal axis, and a flat band (illustrated in FIG. 2) in the F-X line in the vicinity of the Fermi level. These bands means that state density (N (E)) is sharp with respect to the energy in the vicinity of the Fermi level, and thus the Seebeck coefficient can be increased. The Seebeck coefficient can be expressed by δN(E)/δE.

Next, the dimensions of the Full-Heusler alloy of the thermoelectric device selected as described above are determined as follows. First, when the thermoelectric device has the temperature difference of ΔT as defined above, a heat flux Q (W/m²) that flows in the thermoelectric device is Q=κ·(x/L) ·ΔT where using the thermal conductivity κ (W/m·K) of the thermoelectric conversion material, a volume fraction x (%) occupied by the thermoelectric conversion material in the thermoelectric device, and a length L(m) of the thermoelectric conversion material in a thermal gradient direction.

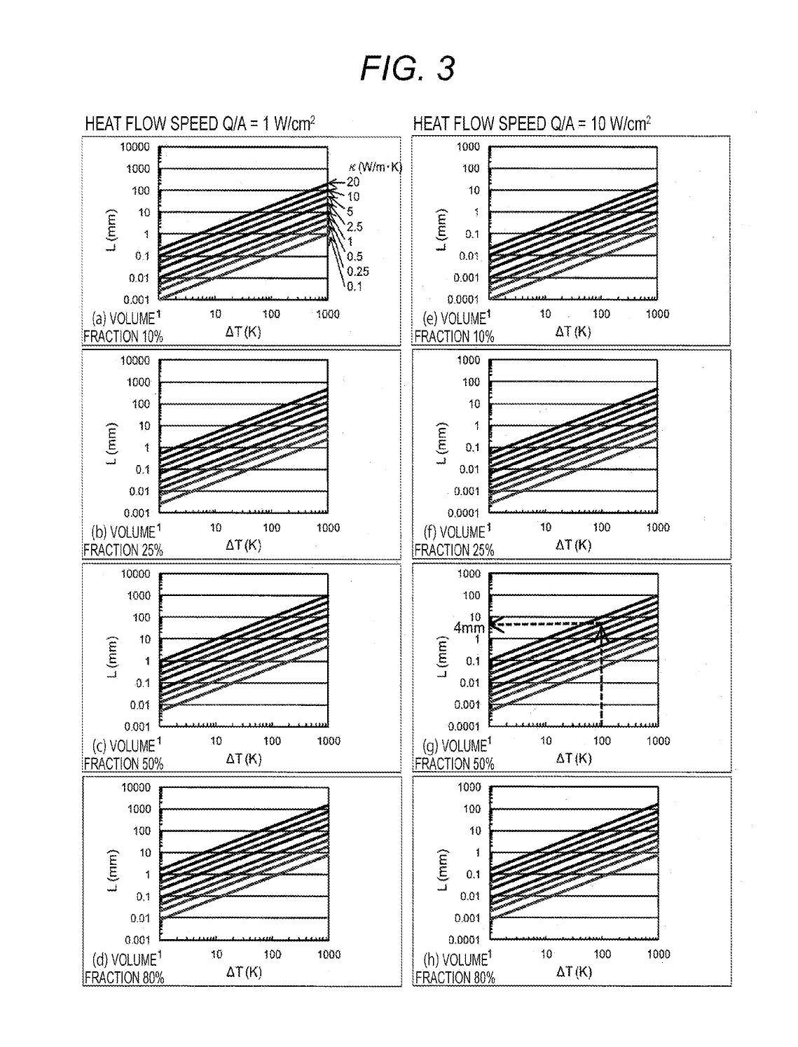

Therefore, L=Q·x/(κ·ΔT) can be given, and a necessary minimum value of the length L (FIG. 1) of the thermoelectric conversion material in the thermal gradient direction is determined according to the temperature difference ΔT, under which the thermoelectric device is used, and κ of the thermoelectric conversion material. Further, the heat flux of 10 W/cm² or more can be obtained by performing of heat extraction of the temperature (T_{L}) at the lower temperature side with water cooling or the like. Meanwhile, when the heat extraction is performed using air cooling or the like, instead of the water cooling, the heat flux may often become 1 W/cm² or less. FIGS. 3 (a) to 3(h) illustrate graphs, plotting the lengths L required when ΔT of the temperature is maintained in the thermoelectric device, with respect to the two heat flux values. κ illustrated in FIGS. 3(a) to 3(h) indicates the thermal conductivity of the thermoelectric conversion material in the thermoelectric device, and the length L depends on κ. Further, the length L also depends on the volume x where the volume occupied by the thermoelectric conversion material in the thermoelectric device is x (%). Here, an example of a method of defining the length L is illustrated with reference to FIG. 3(g). For example, in the thermoelectric device capable of obtaining the heat flux of 10 W/cm² by being provided with a water cooling mechanism at the lower temperature side, when the Heusler alloy having the thermal conductivity of κ=10 W/m·K is used with the volume fraction of 50% under an environment of the temperature difference LT=100 K, the minimum value of the length L of the Heusler alloy in the thermal gradient direction is determined to be 4 mm according to the dotted line of FIG. 3(g). The thermoelectric device manufactured in this way can obtain an output of 10 W/cm² or more, and by use of the Full-Heusler alloy having the figure of merit ZT>1, an output of 0.02 W/device can be obtained where the dimensions of the Heusler alloy are 0.2 cm×0.2 cm×0.4 cm. The output substantially varies according to the type of the Full-Heusler alloy used by the device and the temperature difference, under which the device is used.

Here, an embodiment of when FeTiSn that can realizes a high ZT is used for the thermoelectric conversion material will be described. First, a manufacturing process of the present material will be described. Appropriate composition amounts of powder of Fe, Ti, and Sn are weighted, and the powder is alloyed by a mechanical alloying method. The time of the mechanical alloying is performed until the crystal grain size of the powder becomes 1 μm or less. As the crystal grain size becomes smaller, phonon scattering in the crystal grain boundary becomes larger, and thus the thermal conductivity can be decreased, and ZT is improved. The mechanical alloying may be performed for from several hours to several hundred hours. The fine powder manufactured in this way is formed into a sintered body by a fast sintering furnace. For example, the sintering is performed in a condition where the powder is maintained at 800° C. for 10 minutes, and growth of the crystal grain size is not facilitated by rapid cooling. However, the temperature, the maintaining time, the heating and temperature-rising time, and the cooling and temperature-falling time are controlled, and a sintered material having the grain size of 1 μm or less is applied.

Further, an amorphous material is manufactured by condition control, and can be applied to the thermoelectric device. By forming of the fine crystal grains of 1 μm or less or the amorphous material, the thermal conduction due to lattice vibration is prevented by phonon scattering in the crystal grain boundary, and the thermal conductivity of the FeTiSn based material can be decreased. The thermal conductivity can be decreased to about 1/10 of that of a material in a several ten micron order. The FeTiSn amorphous can realize the thermal conductivity of 2 W/m·K. The Seebeck coefficient of the FeTiSn material is 200 μV/K, and specific resistance is about 1.5 μΩm, and ZT>1 can be realized. Further, by replacement of Sn with Si, the Seebeck coefficient can be maximized up to 600 μV/K, and ZT>2 can be realized.

An output of the thermoelectric device using the FeTiSn Heusler alloy having ZT>2 and the thermal conductivity of 2.5 W/m·K manufactured as described above, and used in the environment of ΔT=100 K will be described. When obtaining the heat flux of 10 W/cm², 1 mm or more is applied to the length L of the FeTiSn in the thermal gradient direction according to FIG. 3(g). Further, in the case of ZT>2, the conversion efficiency becomes 7.4%. Therefore, the output of the thermoelectric device becomes 0.03 W/device when FeTiSn of 0.2 cm×0.2 cm×0.1 cm is used. Further, when FeTiSn is used under an environment of the temperature difference ΔT=200° C., the conversion efficiency of 12.6% can be obtained. Therefore, output density becomes 1.26 W/cm², and a device having 0.05 W/device that is about five times larger than a conventional device can be provided.

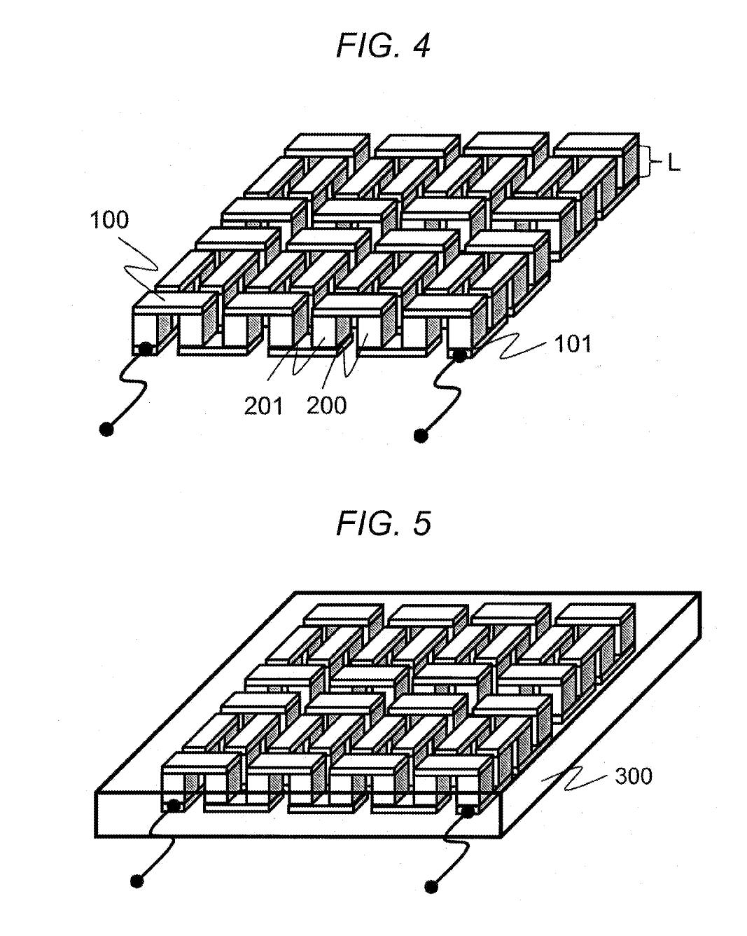

FIG. 4 illustrates a thermoelectric module configured such that a plurality of thermoelectric devices illustrated in FIG. 1 is arranged in a planar manner. The electrodes 100 and 101 illustrated in FIG. 1 serve as electrodes that connect the thermoelectric devices, and are arranged such that the p-type Heusler alloy and the n-type Heusler alloy are always alternately connected. The Heusler alloy used here and its dimensions are similar to those in the case of the thermoelectric device illustrated in FIG. 1. For example, when 100 thermoelectric devices having 0.5 W/device are arranged in the environment of ΔT=100 K described in the embodiment of FIG. 1, an output of 2 W per one module can be obtained. Further, when a similar module using FeTiSn is used in the environment of LT=200° C., an output of 5 W per one module can be obtained.

FIG. 5 illustrates an example of a thermoelectric module in which the thermoelectric module illustrated in FIG. 4 is sealed with SUS in a vacuum interior, or is covered with a resin and secretly packaged. With such packaging, an effect to improve durability against an environment in which vibration or the like is large can be obtained.

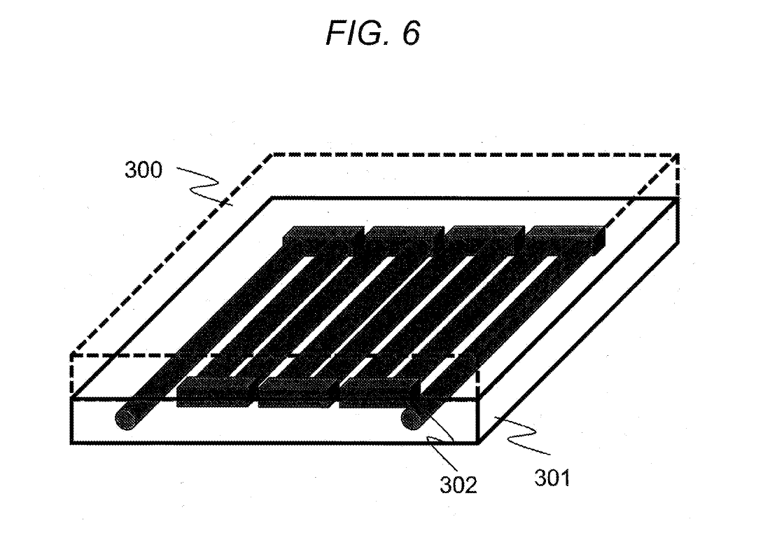

FIG. 6 illustrates a cooling unit 301 in which a thermoelectric module 300 illustrated in FIG. 5 includes piping 302 that enables cooling water or other solvents to flow for efficient heat extraction at the lower-temperature side. By use of the cooling unit 300, a temperature difference is always provided to the thermoelectric module 300 and continuous thermal power generation becomes possible. Further, since the temperature difference can be effectively provided, power generation efficiency can be obtained without decreasing the thermoelectric conversion efficiency.

### REFERENCE SIGNS LIST

100 electrode

101 electrode

102 electrode

200 p-type Heusler alloy

201 n-type Heusler alloy

300 thermoelectric module

301 cooling unit

302 refrigerant piping

1. A thermoelectric device
comprising a pair of Heusler alloys made of an n-type Heusler alloy and a p-type Heusler alloy connected with an electrode, and
taking out electromotive force according to a temperature gradient caused between the n-type Heusler alloy and the p-type Heusler alloy.

2. The thermoelectric device according to claim 1, wherein the Heusler alloy has a length L in a temperature gradient direction, and the length L is κ·ΔT·(x/100)/Q (m) or less where thermal conductivity of the Heusler alloy is κ (W/m·K), a volume fraction in the Heusler alloy device is x (%), a temperature difference of the Heusler alloy in the length L direction is ΔT (K), and a heat flux is Q (W/m²).

3. The thermoelectric devices according to claim 1, wherein the Heusler alloy is configured from Fe, an element X, and an element Y, and the elements X is configured from at least one of Ti, Zr, Hf, V, Nb, Ta, Cr, Mo, W, Sc, and Y, and the element Y is configured from at least one of Si, Ge, Sn, Al, Ga, In, Zn, Cd, Hg, Ca, Sr, Ba, P, As, Sb, and Bi.

4. The thermoelectric device according to claim 1, wherein a crystal grain size of the Heusler alloy is 1 μm or less.

5. The thermoelectric module according to claim 1, wherein a plurality of thermoelectric devices is arranged, and a pair of electrodes for taking out the electromotive force is included.

6. The thermoelectric module according to claim 5, wherein the Heusler alloy has a length L in a temperature gradient direction, and the length L is κ·ΔT·(x/100)/Q (m) or less where thermal conductivity of the Heusler alloy is κ (W/m·K) , a volume fraction in the Heusler alloy device is x (%), a temperature difference of the Heusler alloy in the length L direction is ΔT (K), and a heat flux is Q (W/m2).

7. The thermoelectric module according to claim 5, wherein the Heusler alloy is configured from Fe, an element X, and an element Y, and the elements X is configured from at least one of Ti, Zr, Hf, V, Nb, Ta, Cr, Mo, W, Sc, and Y, and the element Y is configured from at least one of Si, Ge, Sn, Al, Ga, In, Zn, Cd, Hg, Ca, Sr, Ba, P, As, Sb, and Bi.

8. The thermoelectric module according to claim 5, wherein a crystal grain size of the Heusler alloy is 1 μm or less.

9. The thermoelectric module according to claim 5, wherein the thermoelectric module is secretly packaged by vacuum sealing.

10. The thermoelectric module according to claim 5, wherein the thermoelectric module is secretly packaged with a resin.

11. The thermoelectric module according to claim 5, wherein a cooling unit is included at one surface of the thermoelectric module, and piping that enables refrigerant to flow is included in the cooling unit.
